(19) United States
(12) Patent Application Publication
(10) Pub. No.: US 2026/0121597 A1
(43) Pub. Date: Apr. 30, 2026

(54) INPUT TERMINATION OF RADIO FREQUENCY DEVICES DURING CALIBRATION USING TEST EQUIPMENT

(71) Applicant: pSemi Corporation, San Diego, CA (US)

(72) Inventors: Sivakumar Ganesan, Austin, TX (US); James Francis McElwee, Austin, TX (US); Xiaoling Guo, Austin, TX (US); Jing Li, Austin, TX (US); Gregory Frame, Valley Center, CA (US)

(21) Appl. No.: 18/929,458

(22) Filed: Oct. 28, 2024

(51) Int. Cl. H03F 3/19

(52) U.S. Cl. CPC H03F 3/19; H03F 2200/294; H03F 2200/451

(57) ABSTRACT

Radio frequency devices are presented that include input termination paths for use during calibration of these devices using test equipment. In one embodiment, an integrated circuit is disclosed. The integrated circuit may include an input terminal; an amplifier circuit; an input path connecting the input terminal to the amplifier circuit; and a calibration switch connected in series to a resistor to form a calibration path. In some embodiments, the calibration path is connected to the input path, and wherein the calibration switch is configured to be in a closed state during calibration of the amplifier circuit and in an open state after completion of the calibration of the amplifier circuit.

### BACKGROUND

This disclosure relates to electronic radio frequency (RF) devices, and more particularly to calibration of radio frequency (RF) devices using test equipment and associated systems, methods, and devices.

Many modern electronic systems include RF receivers; examples include personal computers, tablet computers, wireless network components, televisions, cable system “set top” boxes, radar systems, and cellular telephones. Many RF receivers are paired with RF transmitters in the form of transceivers. In some cases, RF transceivers are capable of transmitting and receiving across multiple frequencies in multiple bands.

RF transceivers generally include a number of circuits such as amplifiers, oscillators, multipliers, mixers, etc., that utilize an active circuit comprising one or more transistors having a specified current level. Examples of RF circuits and devices include low-noise amplifiers (LNAs), power amplifiers, and other types of amplifiers.

RF circuits, whether stand-alone or as part of a transceiver, are generally fabricated as multiple individual dies or “chips” on a semiconductor wafer. For mass production, each die is generally tested using test equipment, such as automated test equipment (ATE). For electrical testing, a set of probes may be placed in contact with a die (such as via bumps on a die) so as to apply power and measure circuit characteristics (e.g., voltages, currents, capacitances, inductances, impedances, frequencies, and/or logic signals). Testing of RF integrated circuits (ICs) can be challenging owing at least in part to the continuing trend towards smaller die sizes and higher RF frequencies.

For example, while using an ATE to calibrate an RF IC that includes an LNA, a large, undesired inductance may be introduced by test probes or other features of an ATE. Such large inductances can result in instability of the LNA, which can introduce errors in calibration. Thus, there is a need to improve calibration of RF devices, such as LNAs, to improve calibration accuracy.

### SUMMARY

Embodiments of the present disclosure include radio frequency devices that include input termination paths for use during calibration of these devices using test equipment and methods of calibrating such radio frequency devices.

In some aspects, an integrated circuit is disclosed. In some embodiments, the integrated circuit includes an input terminal; an amplifier circuit; an input path connecting the input terminal to the amplifier circuit; and a calibration switch connected in series to a resistor to form a calibration path. In some embodiments, the calibration path is connected to the input path, and wherein the calibration switch is configured to be in a closed state during calibration of the amplifier circuit and in an open state after completion of the calibration of the amplifier circuit.

In some aspects, a device is disclosed. In some embodiments, the device includes a plurality of active circuits; a plurality of input terminals, each of which is coupled to one of the plurality of active circuits in one-to-one correspondence; and a plurality of calibration circuits, each of which comprises a calibration switch connected in series to a resistor to form a calibration path, and each of which is coupled to a corresponding one of the plurality of input terminals in one-to-one correspondence. In some embodiments, each calibration switch is configured to be in a closed state during a calibration mode and in an open state after completion of the calibration mode.

In some aspects, a method of calibrating an integrated circuit is disclosed, wherein the integrated circuit includes an input terminal; a low-noise amplifier circuit; an input path connecting the input terminal to the low-noise amplifier circuit; and a switch connected in series to a resistor to form a calibration path, wherein the calibration path is connected to the input path. In some embodiments, the method of calibrating an integrated circuit includes setting the switch in a closed state; and calibrating the integrated circuit.

The scope of the present disclosure is defined by the claims, which are incorporated into this section by reference. A more complete understanding of embodiments of the present disclosure will be afforded to those skilled in the art, as well as a realization of additional advantages thereof, by a consideration of the following detailed description of one or more embodiments. Reference will be made to the appended sheets of drawings that will first be described briefly.

### DESCRIPTION OF THE DRAWINGS

FIG. 1 illustrates a conventional calibration system, in accordance with one or more embodiments of the present disclosure.

FIG. 2 illustrates a novel calibration system, in accordance with one or more embodiments of the present disclosure.

FIG. 3 illustrates a device, in accordance with one or more embodiments of the present disclosure.

FIG. 4A illustrates another device, in accordance with one or more embodiments of the present disclosure.

FIG. 4B illustrates another device, in accordance with one or more embodiments of the present disclosure.

FIG. 5 illustrates an example test system, in accordance with one or more embodiments of the present disclosure.

FIG. 6 illustrates an example test system, in accordance with one or more embodiments of the present disclosure.

FIG. 7 illustrates a device under test (DUT), in accordance with one or more embodiments of the present disclosure.

FIG. 8 illustrates another example device, in accordance with one or more embodiments of the present disclosure.

FIG. 9 illustrates a different example device, in accordance with one or more embodiments of the present disclosure.

FIG. 10 is a simplified schematic diagram of an embodiment of a multi-input LNA circuit, in accordance with one or more embodiments of the present disclosure.

FIG. 11 illustrates a method of calibrating an IC, in accordance with one or more embodiments of the present disclosure.

Embodiments of the present disclosure and their advantages are best understood by referring to the detailed description that follows. It is noted that sizes of various components and distances between these components are not drawn to scale in the figures. It should be appreciated that like reference numerals are used to identify like elements illustrated in one or more of the figures.

### DETAILED DESCRIPTION

The present disclosure encompasses novel circuits, architectures, systems, and methods that more effectively and efficiently address the configuration and operation of RF devices. It will be appreciated that various improvements disclosed herein encompass innovative circuits, hardware components, architectures, and related logic that are applicable to applications beyond RF devices.

This disclosure recognizes that current techniques for calibrating LNAs and other RF circuits using ATE equipment may use a surface mount device (SMD) resistor connected to a source input of the device being tested. The SMD resistor is used on the ATE test hardware to maintain stability of the device being tested, in which only direct current (DC) testing is typically performed. For example, LNA stability may be dependent on source input termination impedance during calibration using an ATE. However, despite the use of a resistor at input termination on the ATE, there still may be issues with LNA stability.

A large inductance in series with the resistor (SMD) can be present in the ATE to LNA test configuration due to various factors, such as inductance introduced by a probe needle, a long route on test hardware, or a multi-site membrane. A large inductance can introduce the possibility of instability of the LNA during calibration. For example, under certain conditions, an LNA may behave as an oscillator, even when operating in a DC mode during calibration. Instability of an LNA can introduce errors during calibration of the LNA. The LNA should be calibrated appropriately to determine a gate voltage on an internal field effect transistor (FET) that yields the desired current value (e.g., IDD)). Instability of the LNA can introduce errors in this calibration process. As used herein, “calibration” of a device can generally include determining one or more operational settings of the device, such as gate voltages that yield desired currents and making the appropriate settings on the device to yield desired values during operation, and/or testing of the device to determine whether the device fails and should be scrapped.

Disclosed herein are RF circuits, such as LNAs, in which an input termination path is added to the RF circuit input. For example, an RF circuit may be implemented on an IC, and a termination path may be included on the IC and connected to an input to the RF circuit. The termination path may be enabled only during a test or calibration mode and may have no impact on normal operation of the RF circuit. The impedance on the termination path is designed to keep the RF circuit (e.g., LNA) stable during calibration using an ATE without having to add any external components to the test configuration to maintain stability. For example, no additional input termination component may need to be added to the ATE. These and other features are described with respect to the figures presented below.

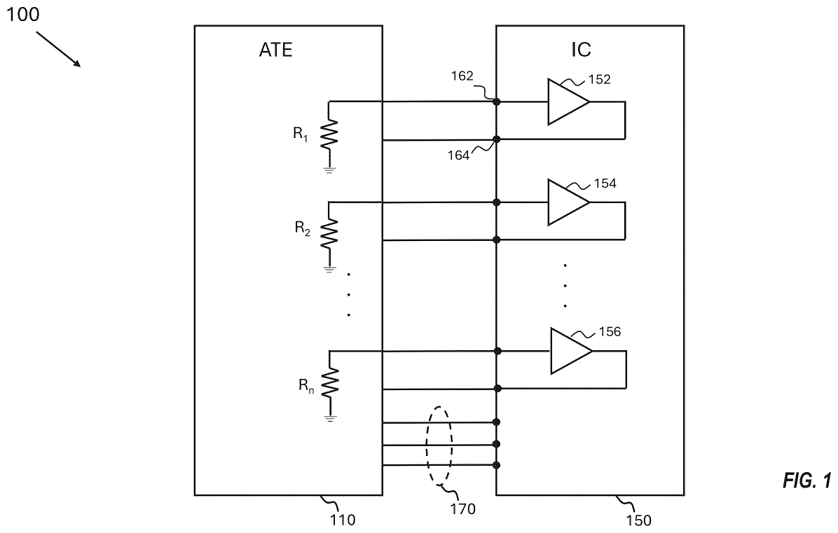

FIG. 1 illustrates a conventional calibration system 100, in accordance with one or more embodiments of the present disclosure. System 100 may include an ATE 110 or other automated test device connected to an IC 150 to perform calibration as shown in FIG. 1. The IC 150 may include one or more amplifiers, in this embodiment labeled as 152, 154, and 156. The amplifiers 152, 154, 156 may be LNAs, for example. The ATE 110 is configured to calibrate the IC 150. For the sake of illustration, one input to each amplifier 152, 154, 156 is illustrated in FIG. 1, but each amplifier may have more than one input, especially for the sake of calibration. For the sake of illustration, one exemplary input terminal 162 is illustrated for amplifier 152, and one exemplary output terminal 164 is illustrated also for amplifier 152. The other amplifiers 154, 156 may also have input terminals and output terminals. The input and output terminals may be implemented as IC bumps or any other type of IC connection, as examples.

The input terminal 162 may ordinarily be connected to an RF input during normal operation of the amplifier 152, and the output terminal 164 may provide an RF output during normal operation of the amplifier 152. Although amplifiers 152, 154, 156 are illustrated in this example, the amplifiers 152, 154, 156 may generally represent any of a number n of active circuits that are implemented on the IC 150.

During calibration of the IC 150 and while the IC 150 is connected to the ATE 110, various signals 170 may be provided to or obtained from the IC 150, and such signals 170 may include an analog voltage supply, a clock signal, and other data and input/output signals. As illustrated by exemplary input terminal 162, the input termination paths are ordinarily terminated by a resistive SMD component with resistances illustrated by R₁, R₂, . . . . Rₙ, with n resistors corresponding to n amplifiers. As explained previously, during testing of an amplifier, such as 152, 154, 156, using the ATE 110, a large, undesired inductance may be introduced by test probes or other features of the ATE 110. Such large inductances can result in instability of the LNA or other amplifier, which can introduce errors in calibration.

This disclosure recognizes that a solution to mitigate the instability issues described herein is to add one or more input termination paths per amplifier on the IC. A termination path may be enabled only through a test mode bit and may have no impact on normal operation. A terminal impedance may be used to maintain amplifier stability during ATE test conditions without having to add any external components to the ATE. These and other techniques are described more fully below.

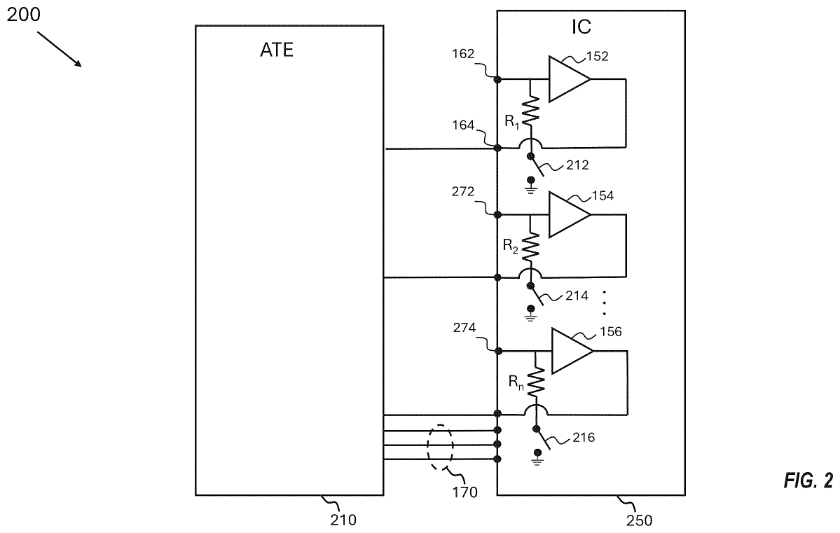

FIG. 2 illustrates a novel calibration system 200, in accordance with one or more embodiments of the present disclosure. System 200 may include an ATE 210 connected to an IC 250 to perform calibration as shown in FIG. 2. Components in FIG. 2 that are the same as FIG. 1 are numbered in the same way. For the sake of illustration, one input to each amplifier 152, 154, 156 is illustrated in FIG. 1, but each amplifier may have more than one input, including for the sake of calibration. An exemplary input terminal 162, 272, and 274 for each amplifier 152, 154, 156, respectively, is illustrated.

For the sake of discussion, the discussion will focus on amplifier 152. There is an input path formed from input terminal 162 to amplifier 152 as shown, and the output of amplifier 152 is connected to output terminal 164. For amplifier 152, there is a calibration path that includes resistor R₁ in series with a calibration switch 212. The calibration switch 212 is configured to be in a closed state during calibration of the amplifier 152 and in an open state otherwise (e.g., after completion of the calibration of the amplifier 152 and during normal operation of the amplifier 152). Each of the switches described herein may be implemented as FET devices or other semiconductor devices using known techniques. Each of amplifiers 154 and 156 likewise also have calibration paths formed from resistors R₂ and switch 214 (for amplifier 154) and formed from resistor Rₙ and switch 216 (for amplifier 156). Each switch (e.g., switch 212) may be controlled using a test mode bit that controls a gate voltage, for example, to open or close the switch, depending on the value of the test mode bit. The termination impedance of a calibration path, such as resistor R₁, R₂, or Rₙ, may be designed to keep the corresponding amplifier (such as an LNA) stable during ATE test conditions. For example, each of resistors R₁, R₂, or Rₙ may be set to about 50 ohms (Ω), or any other exemplary value, such as 40Ω or 60Ω, etc.

Although ATE 210 is shown as not connecting to inputs of amplifiers 152, 154, 156, in some embodiments ATE 210 is connected to inputs of amplifiers 152, 154, 156. Regardless of whether ATE 210 is connected to the inputs of amplifiers 152, 154, 156, one of the advantages of including a calibration path for each amplifier 152, 154, 156 on the IC 250 is that no additional components are needed on the ATE for calibrating the IC.

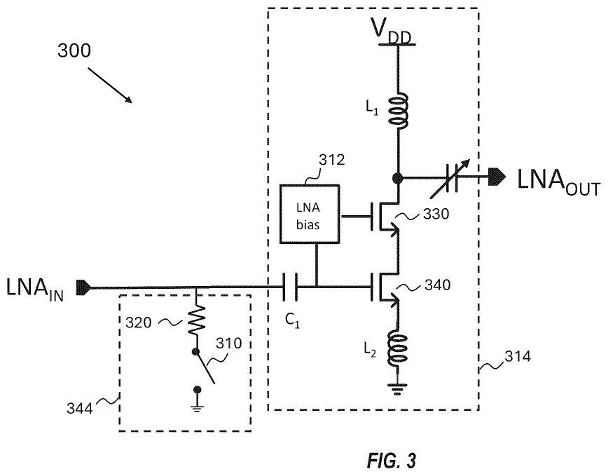

FIG. 3 illustrates a device 300, in accordance with one or more embodiments of the present disclosure. The device 300 may include a calibration path 344 (which may also be referred to as a calibration circuit) and an amplifier circuit 314. In this embodiment, the exemplary amplifier circuit 314 is a LNA. The device 300 may represent a portion of an IC. The LNA input is represented by LNA_{IN} and the LNA output is represented as LNA_{OUT}. The amplifier circuit (LNA) 314 is in the form of a cascode amplifier that includes common gate FET 330 and common source FET 340 in a stacked configuration. The amplifier circuit 314 in this configuration also includes an LNA bias circuit 312 configured to generate DC bias voltages for FETs 330 and 340. In this embodiment, a calibration path 344 includes resistor 320 and switch 310. The device 300 may also include inductors L₁ and L₂ as shown.

During calibration of the amplifier circuit 314, the switch 310 may be in a closed state. For example, during calibration, the device 300 may be connected to ATE (e.g., via connections on the IC that are not shown), such as ATE 210, and there may be no connection between LNA input LNA_{IN} and the ATE. While connected to an ATE, the switch 310 may be in a closed state such that calibration path 344 is enabled, resulting in stable operation of the amplifier circuit 314.

After calibration of the amplifier circuit 314 (such as during normal RF operation of the amplifier circuit 314), the switch may be placed in an open state so that the calibration path 344 does not affect normal operation. During normal operation, the IC is not connected to ATE. In some embodiments, the resistor 320 may be be implemented as a poly resistor and added as part of normal semiconductor processing during formation of the device 300. In addition, the calibration path 344 may optionally be enabled during normal operation of the device 300 to fine tune parameters of the device 300.

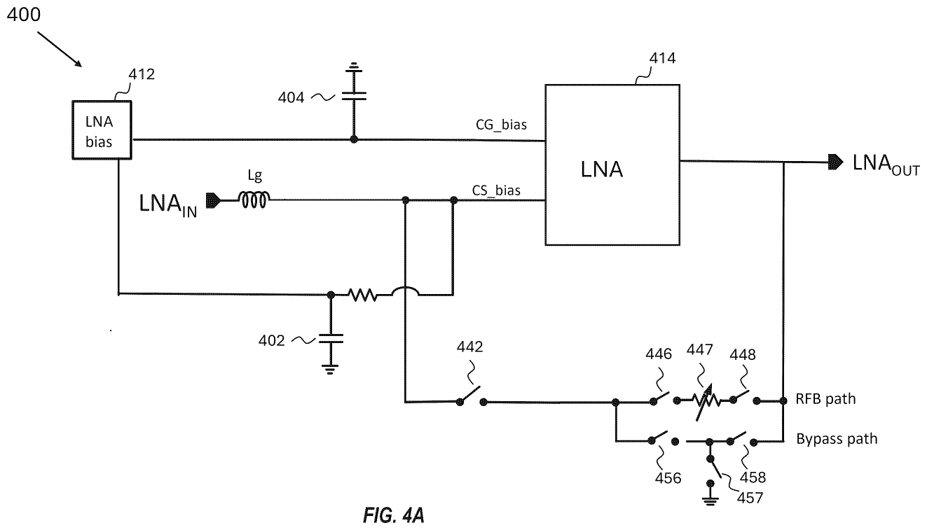

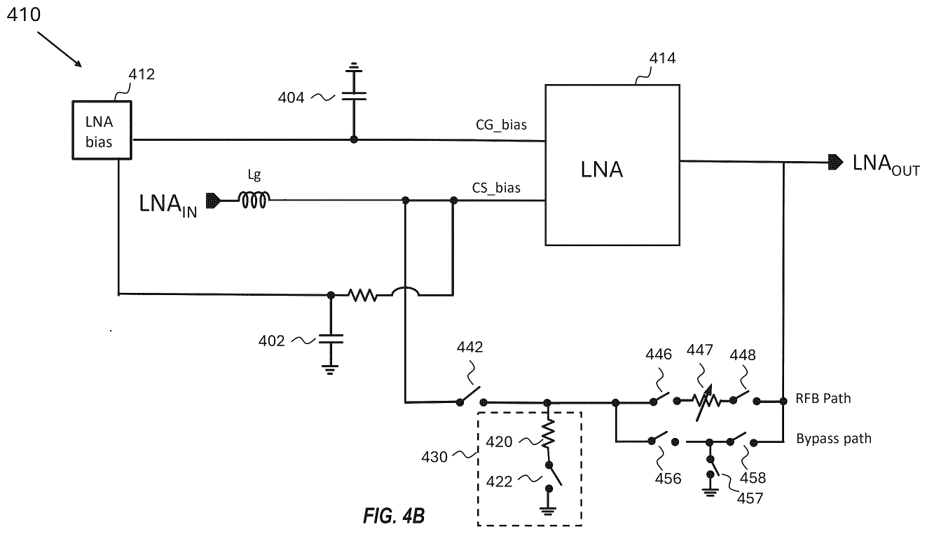

Although the calibration path 344 in FIG. 3 is directly connected to the LNA input, a termination impedance (e.g., resistor 320) may be located in other positions in an IC that is not necessarily directly connected to an LNA input, as shown, for example, in FIG. 4.

FIG. 4A illustrates another device 400, in accordance with one or more embodiments of the present disclosure. The device 400 includes an LNA bias circuit 412 configured to provide one or more DC bias voltages for LNA 414. In this embodiment, the DC bias voltages are labeled as common source (CS) bias CS_bias and common gate (CG) bias CG_bias. The device may further include capacitors 402, 404 as shown. The device 400 may further include bypass paths, which are labeled in FIG. 4A as “RFB path” and “Bypass path.” The feedback path (RFB path) includes a resistor, such as variable resistor 447 which is series-coupled between a pair of switches 446 and 448. The feedback path may be disabled by opening switches 446 and 448 and enabled by closing switches 446 and 448. The bypass path includes bypass switches 456 and 458 operable to enable/disable the bypass path and a shunt switch 457 coupled to a reference potential. The shunt switch 457 coupled in series between the shunt switches 456, 458 forms a T-switch. The device 400 may represent a portion of an IC.

FIG. 4B illustrates another device 410, in accordance with one or more embodiments of the present disclosure. As compared to the device 400, device 410 includes calibration path 430. The RF calibration path 430 includes a resistor 420 in series with a switch 422, which may be implemented using a FET as discussed previously. During calibration (e.g., when device 410 is connected to ATE), the switch 422 is in a closed state such that resistor 420 acts as a termination impedance for LNA 414 to ensure that LNA 414 maintains stability during DC testing. Various other switches, such as switch 442, may also be closed to ensure a circuit connection from LNA input through the calibration path 430 during calibration. The device 410 is an example that demonstrates that a calibration path 430 does not necessarily have to be directly connected at the LNA input LNA_{IN}. The calibration path 430 in this embodiment is indirectly connected to the LNA input LNA_{IN}. The device 410 may represent a portion of an IC.

LNA 414 is shown as a single input LNA having a single LNA core. In some embodiments LNA 414 be a multi-input LNA having two or more inputs with each input connected to an input of an LNA core. In some embodiments, an LNA core of LNA 414 may be a cascode LNA having at least one common-source FET CS and at least one common-gate FET CG series-connected through their respective conduction channels (between drain and source) in a cascode arrangement. In some embodiments, the LNA core of LNA 414 may have two or more CS devices connected in parallel for implementing gain control.

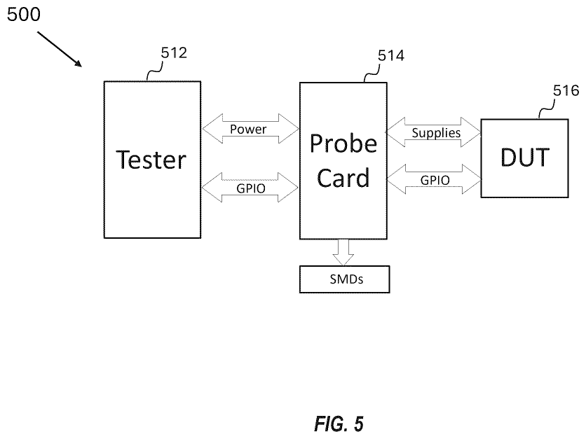

FIG. 5 illustrates an example test system 500, in accordance with one or more embodiments of the present disclosure. The test system 500 includes a device under test (DUT) 516, such as any of the ICs described herein, connected to tester 512 via a probe card 514. The tester 512 may be or include or be part of an ATE. The probe card 514 may be configured to be an interface circuit between the tester 512 (e.g., ATE) and the DUT 516. The probe card 514 may include or may be connected to SMDs, such as termination resistors, as shown. The probe card 514 and tester 512 are connected to the DUT 516 only during testing of the DUT 516, and the probe card 514 and tester 512 are not connected to the DUT 516 during normal operation of the DUT 516.

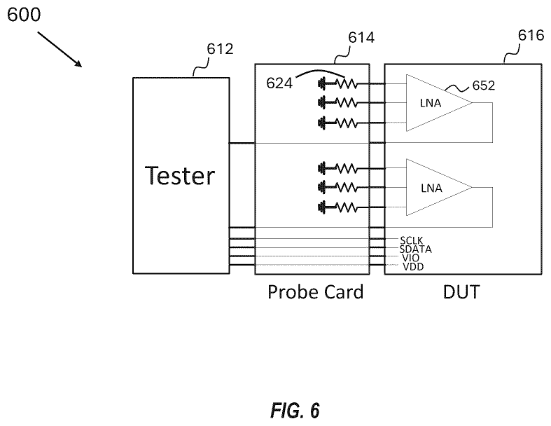

FIG. 6 illustrates an example test system 600, in accordance with one or more embodiments of the present disclosure. The test system 600 includes a device under test (DUT) 616, such as any of the ICs described previously, connected to tester 612 via a probe card 614. The DUT 616 may be an IC that includes a number of LNAs as shown. In this embodiment, the probe card 614 includes termination resistors. An exemplary resistor is labeled as 624, and an exemplary LNA is labeled as 652. There are three inputs to each LNA and three corresponding termination resistors, one for each input in this example. FIG. 6 represents a conventional approach in which termination resistors for the LNAs under test do not reside on the IC with the LNAs.

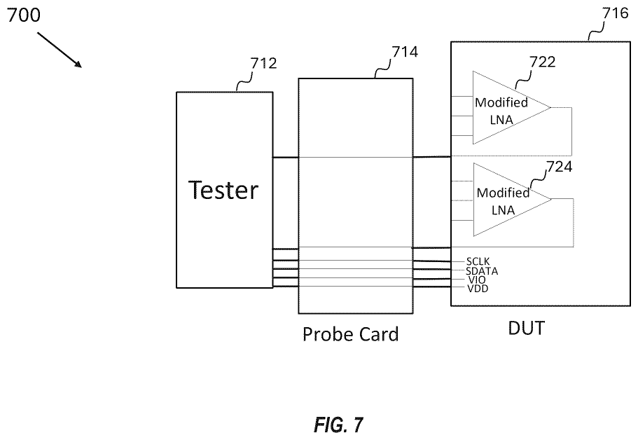

FIG. 7 illustrates a DUT 716 that illustrates the novel approaches for calibrating devices, in accordance with one or more embodiments of the present disclosure. FIG. 7 illustrates an example test system 700 that includes a tester 712, a probe card 714, and a DUT 716. DUT 716 may be implemented as an IC, as described previously. The DUT 716 in this example includes LNA circuits 722 and 724. The LNA circuits 722 and 724 may be modified LNA circuits as described previously as LNA circuits with calibration paths added and coupled to each input. For example, LNA circuit 722 may include a calibration path coupled to each input, such as calibration paths 344 or 430, or calibration paths illustrated in FIG. 2. LNA circuits 722, 724 may be implemented as shown in FIGS. 2 and 4B as examples. Thus, there is no need for probe card 714 to include calibration paths connected to inputs of the DUT 716. The DUT 716 that includes calibration paths (including termination resistors/SMDs) on the DUT 716 can result in a significant reduction in SMD count and hence far fewer routes on the probe card 714 as compared to the probe card in conventional designs, such as shown in FIG. 6. The reduction in probe card complexity can enable simpler hand wired interfaces, which results in lower cost and shorter lead time. In addition, the lower probe card complexity can enable test time reduction by enabling the configuration of robust, multi-side probe cards that configure multiple DUTs (e.g., 48 or 72).

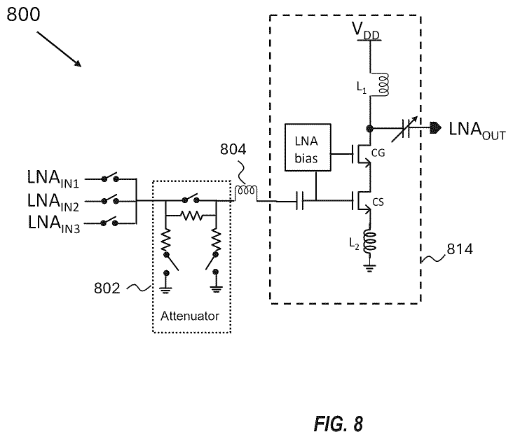

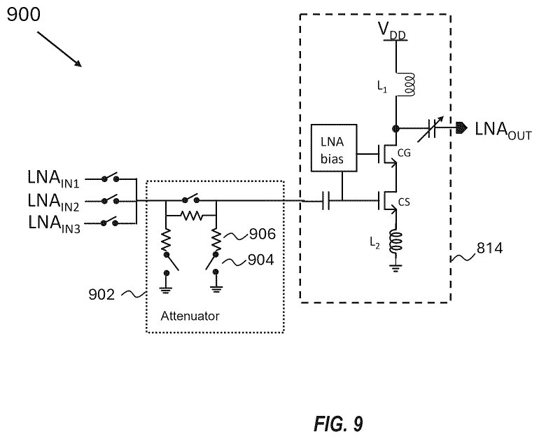

FIGS. 8 and 9 illustrate other example devices, in accordance with one or more embodiments of the present disclosure. FIG. 8 illustrates another example device 800, and FIG. 9 illustrates a different example device 900. The device 800 includes an attenuator 802, a SMD device 804 (an inductor in this example), and an LNA 814. All or part of the device 800 may be implemented in an IC. The device 800 illustrates an LNA architecture that employs a programmable attenuator 802 for gain reduction. A test mode can be added to let the attenuator 802 present a desired impedance to the LNA 814 to maintain stability during calibration. The test mode is described in more detail with respect to FIG. 9. For example, as illustrated in FIG. 9, one of the switches 904 in attenuator 902 may be used to reuse an on-chip attenuator 902 as part of the termination during a calibration procedure. For example, the switch 904 may be in a closed state during calibration (e.g., connection of the device 900 with an ATE) to use the appropriate input impedance during calibration. The resistor 906 and switch 904 may form a calibration path during calibration while also being part of the attenuator 902 during normal operation. The SMD component 804 is optional and may or may not be included in device 900.

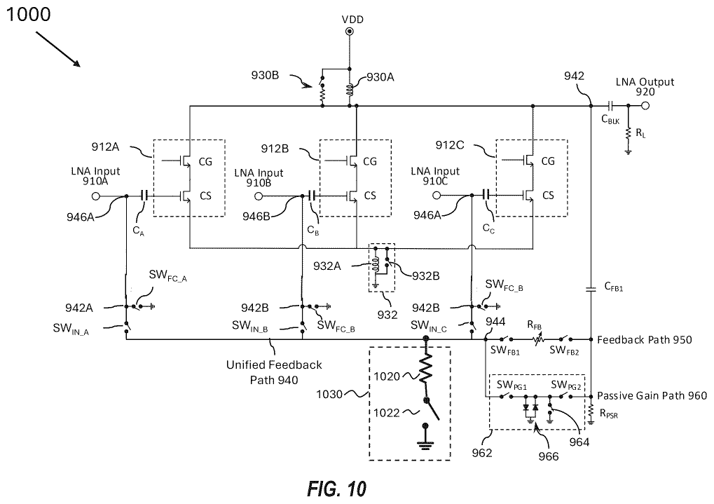

FIG. 10 is a simplified schematic diagram of an embodiment of a multi-input LNA circuit 1000 (alternatively simply called an LNA). The LNA circuit 1000 includes a plurality of inputs, LNA Input 910A, LNA Input 910B, and LNA Input 910C, each providing an input signal source (e.g., an RF signal) to a corresponding amplification core 912A, 912B, and 912C, respectively. Each amplification core 912A-C includes at least one common-source FET CS and at least one common-gate FET CG series-connected through their respective conduction channels (between drain and source) in a cascode arrangement. The gate of each common-source FET CS may be an input terminal of its respective amplification core 912A-C, the source of the common-source FET CS may be a degeneration terminal of its respective amplification core 912A-C, and the drain of the common-gate FET CG may be an amplified signal terminal connected to an output matching network comprised of inductor 930A, resistor 930B and capacitor C_{BLK}. The first capacitor C_{FB1}, the variable resistor R_{FB}, and an input switch SW_{IN} define a feedback signal path for the respective amplification core 912A-C. In some embodiments, capacitors C_{A}, C_{B}, and C_{C} are series-connected to respective amplification cores 912A-C as shown.

Switches SW_{FC_A}, SW_{FC_B}, SW_{FC_C} may be included to form part of the fast charge path. This fast charge path may be used to realize fast gain switching time response, with one switch for each corresponding LNA input. These switches are controlled by a one-shot pulse called FCOS (Fast Charge One Shot) which enables these switches and hence the fast charge path during gain mode transition. This helps quickly charge up the corresponding input capacitor C_{A}, C_{B}, C_{C} to the DC bias voltage as needed for that gain mode. As described above, the bias may be applied between the input capacitor C_{A}, C_{B}, C_{C} and the gate of the CS FET. In some embodiments, the fast charge path may include a resistance in series with the SW. In some embodiments the resistance may be at least the on resistance of the switch.

An optional power supply rejection resistor R_{PSR} may be coupled to the feedback path 950 between a node on the signal path between the first capacitor C_{FB1} and the variable resistor R_{FB}, and the reference potential. In some embodiments, the PSR resistor R_{PSR} may be coupled at other locations in the feedback path 950, such as between the variable resistor R_{FB} and switch SW_{FB1}, or between the variable resistor and switch SW_{FB2}.

The passive gain path 960 includes a circuit 962 implemented to improve return loss and stability in a low gain mode. The passive gain path 960 may further include a shunt switch coupled in series between a plurality of bypass switches to form a T-switch. As illustrated, for example, the circuit 962 includes switches SW_{PG1} and SW_{PG2} operable to enable/disable the passive gain path 960 and a switch 964 coupled to the reference potential.

The optional clamp 966 improves saturation power in the passive gain path 960 without affecting an active gain mode. For example, in a circuit with a large input power, it is often desirable to limit the output power to avoid saturation at the receiver and potential damage to the transceiver. The clamp 966 prevents the large input power from passing through the passive gain path 960 to the LNA output 920. In this approach, saturation power is constrained in low gain mode, while not affecting the active gain mode.

If a simple switch is incorporated in the passive gain path, as opposed to the T-switch of FIG. 10, the Miller effect associated with off capacitance of the switch may cause unwanted degradation of S11. The stability issue can also arise as the off capacitance of the switch starts to have significant impact due to the Miller effect.

In operation, the passive gain path 960 may be disabled by opening switches SW_{PG1} and SW_{PG2} and enabled by closing switches SW_{PG1} and SW_{PG2}. The first capacitor C_{FB1}, the circuit 962, and an input switches SW_{IN_A-C} define a passive gain path for the corresponding amplification core 912A-C.

The unified feedback path 940 combines the feedback path 950 with the passive gain path 960 across the multiple LNA inputs (e.g., LNA input 910A-C in the illustrated embodiment), reducing parasitics and improving RF performance compared to conventional approaches. The unified feedback path 940 may be configured to operate in a high gain mode, a low gain mode, and/or a passive gain mode. The high gain mode may be configured by disabling both the feedback path 950 (e.g., opening switches SW_{FB1} and SW_{FB2}) and disabling the passive gain path 960 (e.g., opening switches SW_{PG1} and SW_{PG2}). The low gain mode may be configured by enabling the feedback path 950 (e.g., closing switches SW_{FB1} and SW_{FB2}) and disabling the passive gain path 960 (e.g., opening switches SW_{PG1} and SW_{PG2}). The passive gain mode may be configured by disabling the feedback path 950 (e.g., opening switches SW_{FB1}, SW_{FB2}), and enabling the passive gain path 960 (e.g., closing switches SW_{PG1} and SW_{PG2}).

Further information on the operation of a multi-input LNA circuit may be found in U.S. patent application Ser. No. 18/784,783, entitled “Multi-Input RF LNA with Unified Feedback Path and Passive Gain Path Systems and Methods,” filed on Jul. 25, 2024, which is hereby incorporated by reference in its entirety.

The multi-input LNA circuit 1000 additionally includes RF calibration path 1030. As shown, the RF calibration path 1030 is connected between SW_{IN} A and a node 944 where the feedback path 950 and the passive gain path 960 connect. The RF calibration path 1030 includes a resistor 1020 in series with a switch 1022, which may be implemented using a FET as discussed previously. During calibration (e.g., when LNA circuit 1000 is connected to ATE), the switch 1022 is in a closed state such that resistor 1020 acts as a termination impedance for amplification cores 912A-C to ensure that amplification cores 912A-C maintain stability during DC testing. The multi-input LNA circuit 1000 is another example that demonstrates that a calibration path 1030 does not necessarily have to be directly connected to any LNA input, such as LNA inputs 910A-C. The calibration path 1030 in this embodiment is indirectly connected to the LNA inputs 910A-C. The LNA circuit 1000 may represent at least portion of an IC. In some embodiments, an IC includes the LNA circuit 1000, and such an IC may be connected to ATE. For example, such an IC may be connected to an ATE as shown in FIG. 2 or 7. For example, one or more of the modified LNAs 722, 724 in FIG. 7 may be implemented as a multi-input LNA circuit 1000.

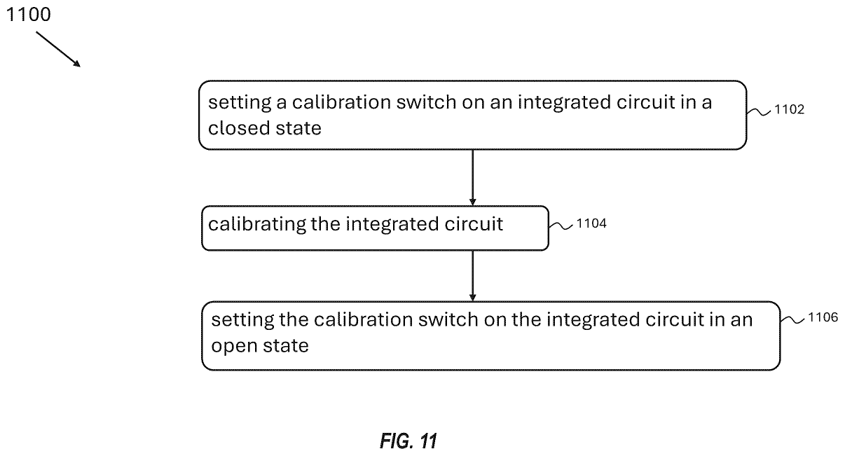

FIG. 11 illustrates a method 1100 of calibrating an IC, in accordance with one or more embodiments of the present disclosure. The IC being calibrated may include an input terminal, a low-noise amplifier circuit, an input path connecting the input terminal to the low-noise amplifier circuit, and a switch connected in series to a resistor to form a calibration path. For example, the IC being calibrated may be IC 250 or may include any of the circuits illustrated in FIG. 3, 4B, 7, 9, or 10. In step 1102, a calibration switch on the IC is set in a closed state. For example, one or more of the calibration switches 212, 214, or 216 in FIG. 2 may be set in a closed state. Next in step 1104, the IC is calibrated. For example, the IC may be calibrated using ATE, e.g., as shown in FIG. 2, and/or using the test configuration illustrated in FIG. 7. Next in step 1106, the calibration switch may be set in an open state and the associated IC may be ready for operation in a normal mode. For example, when the calibration switch is set in an open state, an associated calibration path may have no effect on operation of the IC during normal operation.

Further aspects of the present disclosure include the following:
Aspect 1 includes an integrated circuit comprising: an input terminal; an amplifier circuit; an input path connecting the input terminal to the amplifier circuit; and a calibration switch connected in series to a resistor to form a calibration path, wherein the calibration path is connected to the input path, and wherein the calibration switch is configured to be in a closed state during calibration of the amplifier circuit and in an open state after completion of the calibration of the amplifier circuit.
Aspect 2 includes the integrated circuit of aspect 1, wherein the amplifier circuit comprises a low-noise amplifier.
Aspect 3 includes the integrated circuit of claim 2, wherein the integrated circuit further comprises: a second input terminal; a second amplifier circuit; a second input path connecting the second input terminal to the second amplifier circuit; and a second calibration switch connected in series to a second resistor to form a second calibration path, wherein the second calibration path is connected to the second input path, and wherein the second calibration switch is configured to be in a closed state during calibration of the second amplifier circuit and in a closed state after completion of calibration of the second amplifier circuit.
Aspect 4 includes the integrated circuit of aspect 2, wherein the calibration switch comprises a field effect transistor.
Aspect 5 includes the integrated circuit of aspect 1, wherein the integrated circuit is configured to be calibrated by an automated test device during the calibration of the amplifier circuit.
Aspect 6 includes the integrated circuit of aspect 2, wherein the low-noise amplifier comprises a cascode amplifier comprising a first FET and a second FET in a stacked configuration, and wherein the input path connects the input terminal to a gate of the first FET.
Aspect 7 includes the integrated circuit of aspect 5, wherein the automated test device does not include a termination resistor connected to the input terminal during the calibration of the amplifier circuit.
Aspect 8 includes the integrated circuit of aspect 2, wherein the calibration path is directly connected to the input terminal.
Aspect 9 includes the integrated circuit of aspect 4, wherein the field effect transistor is set in the open state or the closed state depending on a value of a test mode bit.
Aspect 10 includes the integrated circuit of aspect 9, further comprising a programmable attenuator, wherein the attenuator comprises the calibration path.
Aspect 11 includes the integrated circuit of aspect 1, wherein the amplifier circuit is a multi-input low-noise amplifier circuit, wherein the integrated circuit further comprises a plurality of input terminals, wherein the plurality of input terminals comprises the input terminal, and wherein the calibration path is not directly connected to the input terminal.
Aspect 12 includes a device comprising: a plurality of active circuits; a plurality of input terminals, each of which is coupled to one of the plurality of active circuits in one-to-one correspondence; and a plurality of calibration circuits, each of which comprises a calibration switch connected in series to a resistor to form a calibration path, and each of which is coupled to a corresponding one of the plurality of input terminals in one-to-one correspondence, wherein each calibration switch is configured to be in a closed state during a calibration mode and in an open state after completion of the calibration mode.
Aspect 13 includes the device of aspect 12, wherein each of the active circuits comprises a respective amplifier circuit.
Aspect 14 includes the device of aspect 12, wherein each calibration switch comprises a respective field effect transistor.
Aspect 15 includes the device of aspect 12, wherein the device is configured to be calibrated by an automated test device during the calibration mode.
Aspect 16 includes the device of aspect 15, wherein the automated test device does not include a termination resistor connected to any of the plurality of input terminals during the calibration mode.
Aspect 17 includes the device of aspect 13, wherein each amplifier circuit is a low-noise amplifier, wherein each low-noise amplifier comprises a cascode amplifier comprising a first FET and a second FET in a stacked configuration, and wherein each input terminal is connected to a gate of a respective first FET.
Aspect 18 includes the device of aspect 14, wherein each calibration path is directly connected to a corresponding input terminal.
Aspect 19 includes the device of aspect 14, wherein each field effect transistor is set in an open state or a closed state depending on a value of a test mode bit.
Aspect 20 includes a method of calibrating an integrated circuit, wherein the integrated circuit comprises: an input terminal; a low-noise amplifier circuit; an input path connecting the input terminal to the low-noise amplifier circuit; and a switch connected in series to a resistor to form a calibration path, wherein the calibration path is connected to the input path, wherein the method comprises: setting the switch in a closed state; and calibrating the integrated circuit.
Aspect 21 includes the method of aspect 20, further comprising: setting the switch in an open state, after the calibration.
Aspect 22 includes the method of aspect 21, wherein there is no input received at the input terminal during the calibration.

### Fabrication Technologies & Options

The term “MOSFET”, as used in this disclosure, includes any field effect transistor (FET) having an insulated gate whose voltage determines the conductivity of the transistor, and encompasses insulated gates having a metal or metal-like, insulator, and/or semiconductor structure. The terms “metal” or “metal-like” include at least one electrically conductive material (such as aluminum, copper, or other metal, or highly doped polysilicon, graphene, or other electrical conductor), “insulator” includes at least one insulating material (such as silicon oxide or other dielectric material), and “semiconductor” includes at least one semiconductor material.

As used in this disclosure, the term “radio frequency” (RF) refers to a rate of oscillation in the range of about 3 kHz to about 300 GHz. This term also includes the frequencies used in wireless communication systems. An RF frequency may be the frequency of an electromagnetic wave or of an alternating voltage or current in a circuit.

With respect to the figures referenced in this disclosure, the dimensions for the various elements are not to scale; some dimensions have been greatly exaggerated vertically and/or horizontally for clarity or emphasis. In addition, references to orientations and directions (e.g., “top”, “bottom”, “above”, “below”, “lateral”, “vertical”, “horizontal”, etc.) are relative to the example drawings, and not necessarily absolute orientations or directions.

Various embodiments of the invention can be implemented to meet a wide variety of specifications. Unless otherwise noted above, selection of suitable component values is a matter of design choice. Various embodiments of the invention may be implemented in any suitable integrated circuit (IC) technology (including but not limited to MOSFET structures), or in hybrid or discrete circuit forms. Integrated circuit embodiments may be fabricated using any suitable substrates and processes, including but not limited to standard bulk silicon, high-resistivity bulk CMOS, silicon-on-insulator (SOI), and silicon-on-sapphire (SOS). Unless otherwise noted above, embodiments of the invention may be implemented in other transistor technologies such as bipolar, BiCMOS, LDMOS, BCD, GaAs HBT, GaN HEMT, GaAs pHEMT, and MESFET technologies. However, embodiments of the invention are particularly useful when fabricated using an SOI or SOS based process, or when fabricated with processes having similar characteristics. Fabrication in CMOS using SOI or SOS processes enables circuits with low power consumption, the ability to withstand high power signals during operation due to FET stacking, good linearity, and high frequency operation (i.e., radio frequencies up to and exceeding 300 GHz). Monolithic IC implementation is particularly useful since parasitic capacitances generally can be kept low (or at a minimum, kept uniform across all units, permitting them to be compensated) by careful design.

Voltage levels may be adjusted, and/or voltage and/or logic signal polarities reversed, depending on a particular specification and/or implementing technology (e.g., NMOS, PMOS, or CMOS, and enhancement mode or depletion mode transistor devices). Component voltage, current, and power handling capabilities may be adapted as needed, for example, by adjusting device sizes, serially “stacking” components (particularly FETs) to withstand greater voltages, and/or using multiple components in parallel to handle greater currents. Additional circuit components may be added to enhance the capabilities of the disclosed circuits and/or to provide additional functionality without significantly altering the functionality of the disclosed circuits.

Circuits and devices in accordance with the present invention may be used alone or in combination with other components, circuits, and devices. Embodiments of the present invention may be fabricated as integrated circuits (ICs), which may be encased in IC packages and/or in modules for ease of handling, manufacture, and/or improved performance. In particular, IC embodiments of this invention are often used in modules in which one or more of such ICs are combined with other circuit blocks (e.g., filters, amplifiers, passive components, and possibly additional ICs) into one package. The ICs and/or modules are then typically combined with other components, often on a printed circuit board, to form part of an end product such as a cellular telephone, laptop computer, or electronic tablet, or to form a higher-level module which may be used in a wide variety of products, such as vehicles, test equipment, medical devices, etc. Through various configurations of modules and assemblies, such ICs typically enable a mode of communication, often wireless communication.

A number of embodiments of the disclosure have been described. It is to be understood that various modifications may be made without departing from the spirit and scope of the disclosure. For example, some of the steps described above may be order independent, and thus can be performed in an order different from that described. Further, some of the steps described above may be optional. Various activities described with respect to the methods identified above can be executed in repetitive, serial, and/or parallel fashion.

It is to be understood that the foregoing description is intended to illustrate and not to limit the scope of the disclosure, which is defined by the scope of the following claims, and that other embodiments are within the scope of the claims. In particular, the scope of the disclosure includes any and all feasible combinations of one or more of the processes, machines, manufactures, or compositions of matter set forth in the claims below. (Note that the parenthetical labels for claim elements are for ease of referring to such elements, and do not in themselves indicate a particular required ordering or enumeration of elements; further, such labels may be reused in dependent claims as references to additional elements without being regarded as starting a conflicting labeling sequence).

What is claimed is:

1. An integrated circuit comprising:
an input terminal;
an amplifier circuit;
an input path connecting the input terminal to the amplifier circuit; and
a calibration switch connected in series to a resistor to form a calibration path, wherein the calibration path is connected to the input path, and wherein the calibration switch is configured to be in a closed state during calibration of the amplifier circuit and in an open state after completion of the calibration of the amplifier circuit.

2. The integrated circuit of claim 1, wherein the amplifier circuit comprises a low-noise amplifier.

3. The integrated circuit of claim 2, wherein the integrated circuit further comprises:
a second input terminal;
a second amplifier circuit;
a second input path connecting the second input terminal to the second amplifier circuit; and
a second calibration switch connected in series to a second resistor to form a second calibration path, wherein the second calibration path is connected to the second input path, and wherein the second calibration switch is configured to be in a closed state during calibration of the second amplifier circuit and in a open state after completion of calibration of the second amplifier circuit.

4. The integrated circuit of claim 2, wherein the calibration switch comprises a field effect transistor.

5. The integrated circuit of claim 1, wherein the integrated circuit is configured to be calibrated by an automated test device during the calibration of the amplifier circuit.

6. The integrated circuit of claim 2, wherein the low-noise amplifier comprises a cascode amplifier comprising a first field effect transistor (FET) and a second FET in a stacked configuration, and wherein the input path connects the input terminal to a gate of the first FET.

7. The integrated circuit of claim 5, wherein the automated test device does not include a termination resistor connected to the input terminal during the calibration of the amplifier circuit.

8. The integrated circuit of claim 2, wherein the calibration path is directly connected to the input terminal.

9. The integrated circuit of claim 4, wherein the field effect transistor is set in the open state or the closed state depending on a value of a test mode bit.

10. The integrated circuit of claim 9, further comprising a programmable attenuator, wherein the attenuator comprises the calibration path.

11. The integrated circuit of claim 1, wherein the amplifier circuit is a multi-input low-noise amplifier circuit, wherein the integrated circuit further comprises a plurality of input terminals, wherein the plurality of input terminals comprises the input terminal, and wherein the calibration path is not directly connected to the input terminal.

12. A device comprising:
a plurality of active circuits;
a plurality of input terminals, each of which is coupled to one of the plurality of active circuits in one-to-one correspondence; and
a plurality of calibration circuits, each of which comprises a calibration switch connected in series to a resistor to form a calibration path, and each of which is coupled to a corresponding one of the plurality of input terminals in one-to-one correspondence, wherein each calibration switch is configured to be in a closed state during a calibration mode and in an open state after completion of the calibration mode.

13. The device of claim 12, wherein each of the active circuits comprises a respective amplifier circuit.

14. The device of claim 12, wherein each calibration switch comprises a respective field effect transistor.

15. The device of claim 12, wherein the device is configured to be calibrated by an automated test device during the calibration mode.

16. The device of claim 15, wherein the automated test device does not include a termination resistor connected to any of the plurality of input terminals during the calibration mode.

17. The device of claim 13, wherein each amplifier circuit is a low-noise amplifier, wherein each low-noise amplifier comprises a cascode amplifier comprising a first field effect transistor (FET) and a second FET in a stacked configuration, and wherein each input terminal is connected to a gate of a respective first FET.

18. The device of claim 14, wherein each calibration path is directly connected to a corresponding input terminal.

19. The device of claim 14, wherein each field effect transistor is set in an open state or a closed state depending on a value of a test mode bit.

20. A method of calibrating an integrated circuit, wherein the integrated circuit comprises:
an input terminal;
a low-noise amplifier circuit;
an input path connecting the input terminal to the low-noise amplifier circuit; and
a switch connected in series to a resistor to form a calibration path, wherein the calibration path is connected to the input path, wherein the method comprises:
setting the switch in a closed state; and
calibrating the integrated circuit.

21. The method of claim 20, further comprising:
setting the switch in an open state, after the calibration.

22. The method of claim 21, wherein there is no input received at the input terminal during the calibration.
